(19) United States
(12) Patent Application Publication
(10) Pub. No.: US 2002/0177266 A1
(43) Pub. Date: Nov. 28, 2002

(54) Selectable output edge rate control

(76) Inventors: Christian Klein, Portland, ME (US); Myron J. Miske, Newfields, NH (US)

Correspondence Address: CESARI AND MCKENNA, LLP, 88 BLACK FALCON AVENUE, BOSTON, MA, 02210, US

(21) Appl. No.: 10/153,449

(22) Filed: May 22, 2002

Related U.S. Application Data
(60) Provisional application No. 60/293,361, filed on May 24, 2001.

(51) Int. Cl. H01L 21/8238

(52) U.S. Cl. 438/200

(57) ABSTRACT

A circuit using current starved pull up and pull down transistors is arranged to connect a current source via each transistors to an output transistor stage. The current source values are selected so that the starved transistors provide a known voltage edge rate profile as a function of the current sources and the parameters of the transistors. Two or more additional current sources, that when enabled contribute current in parallel with the first current sources such that controlled edge rate profiles are selectively speeded up in response the enabled current sources. An enable input is provided for each additional current source for selectably controlling the faster or slower edge rate profiles. Reference voltages are used to determine the current source values along with transistor parameters. Preferably the transistor are MOSFETs.

### CROSS-REFERENCE TO RELATED APPLICATIONS

The present application claims the benefit of U.S. Provisional Patent Application Serial No. 60/293,361, which was filed on May 24, 2001, of common inventorship and title with the present application and which provisional application is hereby incorporated herein by reference.

### BACKGROUND OF THE INVENTION

1. Field of the Invention

The present application relates to integrated circuits and more particularly to integrated circuits with controlled output edge slew rates.

2. Background Information

Higher data speeds and/or power and temperature requirements have acted to reduce logic voltage swings and dictate slew rates of the output signals. Logic levels of 5.0 and 3.3 volts are giving way to logic swings of the hundreds or tens of milli-volts.

These requirements are manifest, inter alia, in buffers and drivers, and often in open drain configurations where the external pull up can be referenced to virtually any voltage that the designer might select for compatibility. The open drain also allows, as is well known in the art, for a direct implementation of an “oring” function by connecting the open drains to each other.

Another limitation of high logic level circuits, when driven at higher speed with high rates of change of the signals, is the increased noise and power dissipation that are inherently generated. For example, when a number of buffers switch, the high dv/dt edges will produce excessive currents that generate increased noise and dissipate more power. The noise, broadly speaking, is a function of common impedances and electrostatic and electromagnetic coupling mechanisms that are susceptable to the higher rates of change. Additionally, ringing in the circuits due to transmission line effects and other inductive and capacitive components will typically be higher and last longer than with slower signal edges.

U.S. Pat. No. 5,977,790 discloses programmable slew rate (edge rate) control circuits. The technique uses multiple transistors and gate function with a resistance (or equivalent) determining the slew rates. This particular design is limited since it uses many components that inherently occupy a large portion of a die. U.S. Pat. No. 5,489,862, by the same inventor, discloses a feedback slew rate control circuit, but the slew rate control is not programmable.

U.S. Pat. No. 5,537,070 discloses a slew rate control circuit using a reference voltage and current source, but only controlling the high to low output transition of an open drain circuit. The low to high output transition is purposely unaffected in this invention.

One approach to these limitations is to provide a circuit that has a selectable controlled signal edge rate in both directions. Preferred embodiments may also be arranged to translate to output logic signal levels that are much different than the input levels.

It is an objective of the present invention to provide apparatus and a method for selecting and controlling output signal edge rates.

### SUMMARY OF THE INVENTION

In view of the foregoing background discussion, the present invention provides a circuit with an active pull up and a pull down device. These active devices, in preferred embodiment, may be bipolar or field effect devices or combination thereof. An input signal drives the control gates or bases of the transistors.

The pull up and pull down transistors' drains or collectors are each connected to current sources that are designed to starve the transistors so that the circuit's output positive and negative voltage swings have controlled edge rate profiles. The control is a function of the current sources and the particular transistors involved. Being starved the transistors involved do not switch abruptly—they go through an analog type action thereby allowing the edge rate profiles to be controlled. Practitioners in the art are familiar with handling the specific parameters to achieve the desired edge rate profiles. In a preferred embodiment, the circuit is an inverter that drives an output transistor stage to provide an output with edge rate profiles that correspond to the inverter controlled edge rate profiles.

A preferred example of the invention provides a third current source that can be switched in parallel to the first current source and a fourth current source that can be switched in parallel with the second current source. When switched in these additional current sources speed up the edge rate profiles of inverter output and thereby the output from the output transistor stage. The switch function may be a series connected on/off solid state switches or circuit means that disable the current sources without making a disconnect. Both such circuits are well known in the art.

In a preferred embodiment, the current source values are a function of and controlled by reference signals, one for the current sources connected to the pull up and one for the sources connected to the pull down. Separate controlled mechanisms may be used for each current source, and other means, as known in the art, may be used to determine the values of these current sources. In yet other preferred embodiments many additional current sources may be used where each additional current source or groups of current sources may be enabled by additional logic control signals for selectively programming the output edge rate profiles.

In another preferred embodiment the output transistor stage is a single pull down transistor with a drain or collector connected to a pull up resistor. In this case the pull up resistor may be connected to a power rail of virtually any voltage. In another preferred embodiment the output transistor stage includes a pull up transistor in addition to the pull down. Here the control inputs to these two transistors are connected and driven from the inverter output. Again, these transistors are designed and constructed to provide a controlled edge rate profile corresponding to the edge rate profiles produced from the inverter output.

It will be appreciated by those skilled in the art that although the following Detailed Description will proceed with reference being made to illustrative embodiments, the drawings, and methods of use, the present invention is not intended to be limited to these embodiments and methods of use. Rather, the present invention is of broad scope and is intended to be defined as only set forth in the accompanying claims.

### BRIEF DESCRIPTION OF THE DRAWINGS

The invention description below refers to the accompanying drawings, of which:

FIG. 1 is a schematic block diagram illustration of an embodiment of the invention;

FIG. 2 is a more specific circuit schematic of the inverter circuit in FIG. 1;

FIG. 3 is a schematic of an illustrative example embodying the present invention;

FIG. 4 is a schematic of an illustrative example embodying the invention; and

FIG. 5 is an input/output timing chart for an embodiment of the circuit in FIG. 3

### DETAILED DESCRIPTION OF AN ILLUSTRATIVE EMBODIMENT

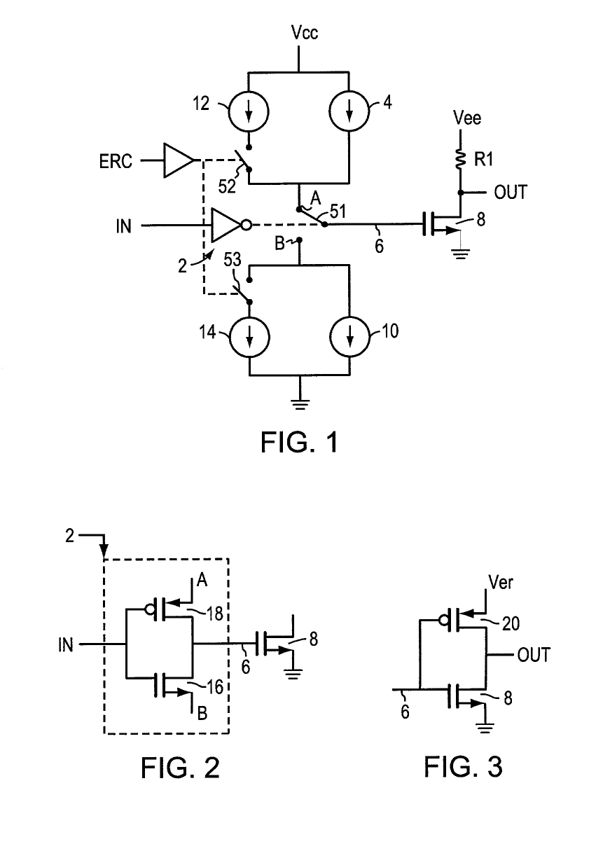

FIG. 1 is a simplified schematic block diagram illustrating an embodiment of the present invention. The IN signal is a logic signal traversing from valid low to valid high voltage levels. Here, ground and Vcc are used, but virtually any other logic level voltage may be used. The inverter 2 is illustrated as a single pole double throw switch S1, that switches at the threshold of the inverter 2.

In FIG. 1, the IN signal when low drives the switch S1 to position A, as shown, the current source 4 drives the gate 6 of the output transistor 8 high thereby turning on the transistor 8 which drives the OUT low. When the IN signal is high the switch is in position B and the current source 10 drives the gate 6 low turning off transistor 8, whereupon R1 pulls the OUT high.

The current source 4 is designed with respect to the rest of the circuit, including the equivalent capacitance at the gate 6, to drive the gate 6 high at a designed rate, and so 5 the OUT signal is driven low after a designed delay and then at a designed edge rate. The delay will be the time it takes the current source 4 to drive the gate 6 to the threshold of transistor 8. The edge rate of the OUT signal will be determined by the particular characteristics of transistor 8 and the known static and transient load on the OUT signal. The edge rate at the OUT is controlled by controlling the voltage rate of change at the gate of transistor 8.

The current source 10 will drive the gate 6 low and have a delay and edge rate effect on the OUT signal going high as did the current source 4 for the OUT going low. But, as one skilled in the art will understand, the OUT is driven high primarily by the load on the OUT signal and the lowering drain current in transistor 8 as it is turned off.

Still referring to FIG. 1, the edge rate control (ERC) signal drives the two switches S2 and S3. When ERC is high both switches, in this embodiment, are “made” and the current source 12 adds to current source 4 via S2, and current source 14 adds to current source 10 via S3. When the current sources 12 and 14 are operative and adding to the current sources 4 and 10 respectively, the delays will be shorter and the edge rates will faster.

FIG. 2 shows an implementation of the inverter 2. Here the switch S1 is formed by: an NMOS 16 with its gate connected to the IN signal, its drain connected to the gate 6 and its source to position B; and by a PMOS 18 with its gate connected to the IN signal, its drain connected to the gate 6 and its source connected to position A. The NMOS and PMOS act in tandem making and breaking the connections between the gate 6 and positions A and B. In an example the current sources 4 and 6 from FIG. 1 provide a small current that “starves” the related transistors 16 and 18. In this way the voltage translation profiles both positive and negative going at the gate of transistor 6 are controlled, thereby controlling the voltage transition edges at the OUT node. When the additional current sources 12 and 14 are driving the gate of transistor 6, the transistors 16 and 18 remain current starved at a different level, but still the gate voltage transition and the output voltage transitions are controlled. As mentioned above the current starved transistors involved do not switch abruptly—they go through an analog type action thereby allowing the edge rate profiles to be controlled.

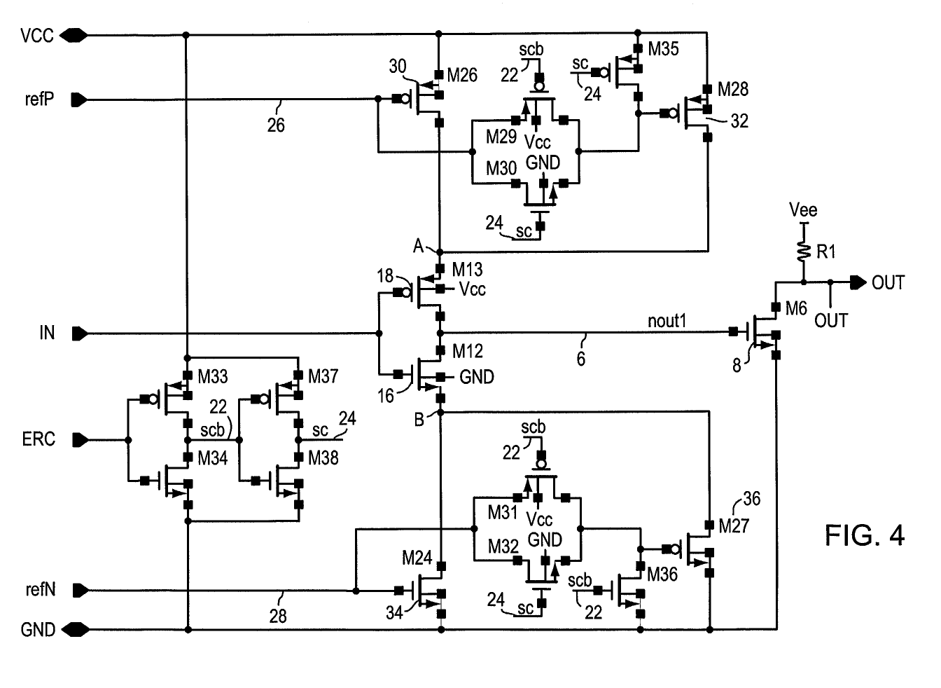

“Starved” inverter topology refers to using current sources in the sources of an inverter transistors. For example, the NMOS and PMOS of FIG. 2 where the sources are connected to the current sources 10 and 14 for the NMOS and 4 and 12 for the PMOS. These current sources are designed to limit the current available to the succeeding stages, in FIG. 1, the NMOS transistor 8. Referring to FIG. 4, when the PMOS 18 is turned on the current that is supplied to the gate 6 of NMOS 8 by the current sources consisting of PMOS 30 and PMOS 32. The value of these current sources is determined by the sizes of the transistors, the reference voltage 26. When NMOS 16 is on, the corresponding current sources are formed from the transistors 34 and 36. The time rate at which the voltage edge at the gate of transistor 8 will be completely determined by the current sources discussed above, and by selecting the reference voltages 26 and 28 and the known transistor parameters the designer can control the edges at the gate 6 and thereby at the OUT signal.

FIG. 3 is a schematic showing an output stage that is not an open drain arrangement. There is a PMOS pull up transistor that drives the OUT signal positive to Vee in a fashion equivalent to transistor 8 pulling the OUT signal to ground.

FIG. 4 is a illustration of a completed open drain circuit. The inverter 2, made up of transistors 18 and 16, is shown driving the output transistor 8 gate 6. The output transistor 8 drain is connected to the OUT with a resistor R1 pull up to a voltage rail Vee.

The input signal ERC is shown as an input to an inverter consisting of M33 and M34. The inverter output is referenced as scb 22. This scb 22 signal is input to another inverter consisting of M37 and M38 with an output signal referenced as sc 24.

The point A is connected to the drain of M26 whose gate is connected to a reference voltage 26. This reference voltage 26 is selected to bias M26 to provide the current source 4 from FIG. 1. This current source value is selected, along with the other current sources described below, to achieve the desired edge rates. When the ERC signal is high the sc signal driving the gates of M35 and M30 high and the scb signal is low driving the gate of M29. M35 is turned off and M30 and M29 are turned on. In this condition the reference voltage 26 is passed through the on transistors M30 and M29 to the gate of M28. In this state M28 forms the current source 12 driving point A. This state is the same as if switch S2 in FIG. 1 is closed.

M30 and M29 are provided in parallel to ensure a low impedance path between the reference 26 and the gate of M28. In other examples one transistor may be used instead of M30 and M29. In yet other examples the circuitry may be implemented with bipolar components including bipolar transistors and diodes or a combination of bipolar and MOS conponents.

When the signal ERC is low, scb 22 is high and sc 24 is low holding M30 and M29 off and M35 on, which turns off M28 and thus the current source 12 (FIG. 1) is disabled or off. This is equivalent to the switch S2 in FIG. 1 being opened.

The operation of the circuitry connected to point B is similar in operation to that described just above. There is a voltage reference 28 driving the gate of M24 wherein M24.

Still referring to FIG. 4, when ERC is low, M36 is on, and M32, M31 and M27 are all off. The transistor M27 is off so the current source 14 (FIG. 1) is disabled or off. This is equivalent to S3 (FIG. 1) being opened. When ERC is high M27 is on and the current source 14 is on and driving point B.

The specific circuit values, voltage and current levels and the values of the programmable controlled edges are functions of the processes, operating environments and the applications. In one example where the input logic levels are 0 to 3.3 volts. FIG. 4 shows the relative IN and OUT signal on the same graph. In this example the current sources, referencing FIGS. 4 and 10 are about one milliamp and sources 12 and 14 are also about one milliamp. R1 is twenty-five ohms and Vee is about 1.5 volts. In this case the width to length of the transistors 30 and 32 are the same.

Practitioners in the art will understand how to design transistors to provide virtually any reasonable current.

The current sources 4 and 12 are both controlled by the reference voltage 26, and so track each other. This is also true for current source 10 and 14 both of which are controlled by reference voltage 28.

In other illustrative examples, as those skilled in the art will understand, other values for logic levels, both input and output, and current levels can be used to advantage. Moreover,

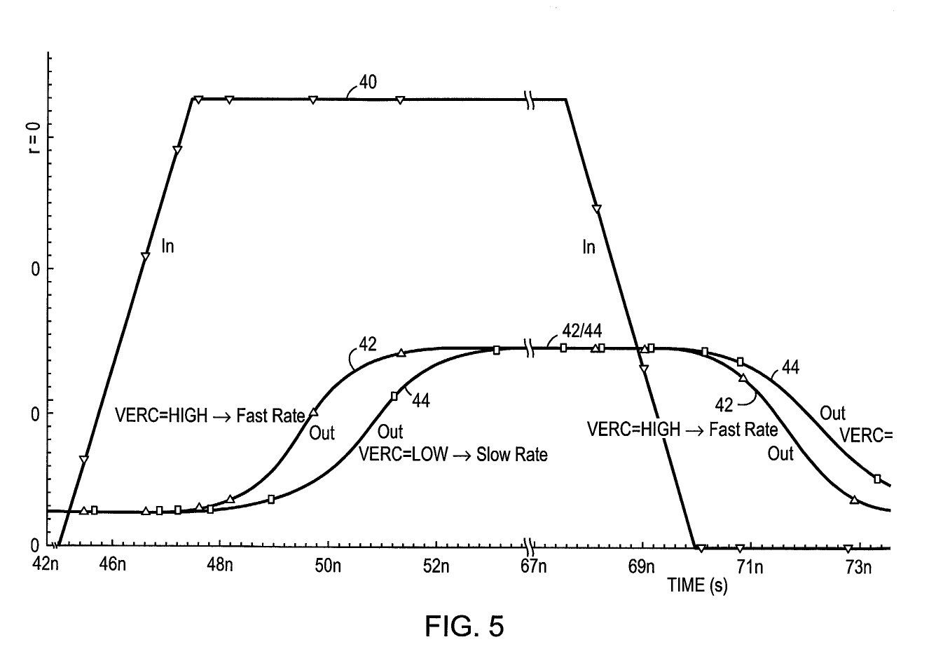

FIG. 5 shows an input/output signal comparison as measured on a circuit as shown in FIG. 4. The input signal 40 traversing 0 to 3.3 volts and the output signal 0.25 to 1.5 volts. When, the ERC signal is high the output signal 42 is produced, and when ERC is low the output signal 44 is produced. As is evident, output signal 42 has less delay and rises faster that signal 44. When the input goes low edge where signal 42 lowers faster with less delay than signal 44.

It should be understood that above-described embodiments are being presented herein as examples and that many variations and alternatives thereof are possible. Accordingly, the present invention should be viewed broadly as being defined only as set forth in the hereinafter appended claims.

What is claimed is:

1. A circuit comprising:
an inverter defining a first input and first output and two states,
a first state with an on pull up transistor and a second state with an on pull down transistor,
a first current source connected to the pull up transistor and a second current source connected to the pull down transistor, wherein when in the first state the first current source provides current to the output, and in the second state the second current source provides current to the first output,
a third current source in parallel with the first current source and a fourth current source in parallel with the second current source,
means for selectively enabling and disabling the third current source from adding to the first current source,
means for selectively enabling and disabling the fourth current source from adding to the second current source, wherein
the voltage edge rate profiles of the first output are controlled when going positive and negative.

2. The circuit of claim 1 wherein the means for selectively enabling and disabling the third current source comprises a first transistor switch with a control node, and input logic signal connected to the control node, wherein when the input logic signal is in one state the first transistor switch is on enabling the third current source in parallel with the first current source, and, when the input logic signal is in another state, the third current source is disabled and not in parallel.

3. The circuit of claim 1 wherein the means for selectively enabling and disabling the fourth current source comprises a second transistor switch with a control node, and an input logic signal connected to the control node, wherein when the input logic signal is in one state the second transistor switch is on enabling the third current source in parallel with the second current source, and, when the input logic signal is in another state, the fourth current source is disabled and not in parallel.

4. The circuit of claim 1 further comprising an output transistor stage defining an second output and a control input connected to the first output, wherein the output transistor stage, in response to the first output voltage edge rate profiles, provides corresponding second output voltage edge rate profiles.

5. The circuit of claim 1 wherein the current sources are constructed to starve the pull up and pull down transistors thereby defining the voltage output edge rate profiles.

6. The circuit of claim 1 further comprising a first reference source configured to determine the current value of the first and the third current sources and a second reference voltage configured to determine the value of the second and the fourth current sources.

7. The circuit of claim 6 further comprising a first transistor switch with a first control node,
a second transistor switch with a second control node, and
an input logic signal connected to the first and second control nodes, wherein when the input logic signal is in one state the first transistor switch is on connecting the first reference source to the third current source and enabling it in parallel with the first current source and, when the input logic signal is in another state, the third current source is disabled, and when the input logic signal is in one state the second transistor switch is on connecting the second reference source to the fourth current source enabling it in parallel with the second current source and, when the input logic signal is in another state, the fourth current source is disabled.

8. The circuit of claim 2 wherein the output transistor stage comprises a pull up transistor and a pull down transistor.

9. The circuit of claim 8 wherein the output transistor stage comprises a PMOS pull up field effect transistor and an NMOS pull down field effect transistor.

10. The circuit of claim 2 wherein the output transistor stage comprises a pull down transistor and a pull up resistor connected to the second output.

11. The circuit of claim 6 wherein the first and the third current sources comprise a first and a third transistor with a first and a third control input, respectively, wherein, when the first reference voltage is connected to the first and third control inputs, the first and third transistors are designed and constructed to provide a first and third current, respectively.

12. The circuit of claim 6 wherein the second and the fourth current sources comprise a second and a fourth transistor with a second and a fourth control input, respectively, wherein, when the second reference voltage is connected to the second and fourth control inputs, the second and fourth transistors are designed and constructed to provide a second and fourth current, respectively.

13. The circuit of claim 1 further comprising a first plurality of additional current sources arranged in parallel with the first current source, and a second plurality of current sources arranged in parallel with the second current source, and
means for selectively enabling each of said first and second plurality of current sources, wherein the voltage edge rate profiles of the first output are selectively controlled when going positive and negative by correspondingly enabling said current sources from the first and the second plurality of current sources.
